(19) United States
(12) Patent Application Publication
(10) Pub. No.: US 2009/0120481 A1
(43) Pub. Date: May 14, 2009

(54) Multi-Functional Energy Converter

(75) Inventor: Xiaomei Yu, Glastonbury, CT (US)

Correspondence Address: OHLANDT, GREELEY, RUGGIERO & PERLE, LLP, ONE LANDMARK SQUARE, 10TH FLOOR, STAMFORD, CT, 06901, US

(73) Assignee: Carrier Corporation

(21) Appl. No.: 12/085,090

(22) PCT Filed: Nov. 17, 2005
(86) PCT No.: PCT/US2005/041502

§ 371 Date: May 15, 2008

(51) Int. Cl. H01L 35/28

(52) U.S. Cl. 136/204

(57) ABSTRACT

A system (10) for converting energy having an array of thermoelectric devices (60) connected electrically in series between a first heat exchanger (15) in contact with a first surface (61) of the array and a second heat exchanger (20) in contact with a second surface (63) opposite the first surface of said array (60). The array (60) is capable of generating a DC current while a thermal gradient between the first surface and the second surface is applied. When DC current is applied to said array, either waste heating or waste cooling is produced at a working surface.

### BACKGROUND OF THE INVENTION

1. Field of the Invention

This invention relates to an energy converter that is capable of directly converting between the thermal and electrical energy as part of an integrated cooling, heating, and power (CHP) system where waste heat and electrical power are abundant and accessible.

2. Description of Related Art

An integrated CHP system faces challenges to meet simultaneously cooling, heating, and electric loads in a variety of applications and environments. The characteristics of the different loads require that integrated CHP systems have flexible operating modes-and offer flexible cooling, heating and power capacity. While conventional CHP solutions can be used to meet primary loads, supplemental cooling, heating, and power generation systems must be used to meet fluctuated loads at various times of a day or seasons. Conventionally, grid power is used, in addition to a CHP system to meet the need of additional electric load. A vapor compression system is used to meet the need of additional cooling load. A heating system is used to meet the need of additional heating load. The conventional solutions are bulky, noisy, require complex control systems and often take a longer time to achieve a satisfactory cooled or heated condition. Thus they are inconvenient and inefficient. Further, current conventional systems are still dependent on grid power and have lower system reliability because they have many moving parts.

Therefore, there exists a need for an energy converter that can directly convert between thermal energy (heat rejected or absorbed) and electrical energy (electricity), as a buffering system, to meet the need of various loads that supplemental systems of a conventional CHP system are able to independently meet.

### SUMMARY OF THE INVENTION

It is an object of the present invention to provide a multi-functional energy converter that is capable of directly converting between electrical and thermal energy using a single system.

It is also an object of the present invention to provide a multi-functional energy converter that uses an array of thermoelectric elements to convert directly between electrical energy and thermal energy (cooling and heating) using a single system.

It is a further object of the present invention to provide a multi-functional energy converter that applies a thermal gradient to an array of thermoelectric elements to generate a voltage across the thermoelectric elements.

It is yet a further object of the present invention to provide a multi-functional energy converter that creates cooling at one surface of the thermoelectric elements and creates heating at another surface of the thermoelectric elements opposite the cool surface when a DC voltage is applied across the array of elements.

These and other objects of the present invention are provided by an array of thermoelectric elements connected electrically in series between a first heat exchanger in contact with a first surface of the array, the first surface being a working surface, and a second heat exchanger in contact with a second surface opposite the first surface of the array. The array of thermoelectric elements is capable of generating a DC current while applying a temperature gradient between the first surface and the second surface. The array of thermoelectric elements is also capable of providing thermal energy to a fluid or withdrawing thermal energy from a fluid at said working surface from waste heating or cooling at the working surface.

A system for converting energy having an array of thermoelectric elements connected electrically in series is provided. The system also provides for a first substrate covering one surface of the array and second substrate covering a second surface of the array that is opposite the first surface of the array, the first surface being a working surface. The array of thermoelectric elements is capable of generating a DC current while a temperature gradient between the first substrate and the second substrate is applied or providing thermal energy to said working surface.

### BRIEF DESCRIPTION OF THE DRAWINGS

FIG. 1 illustrates a first embodiment of the present invention configured for a power generation mode;

FIG. 2 illustrates a second embodiment of the present invention configured for a cooling mode; and

FIG. 3 illustrates a third embodiment of the present invention configured for a heating mode.

### DETAILED DESCRIPTION OF THE INVENTION

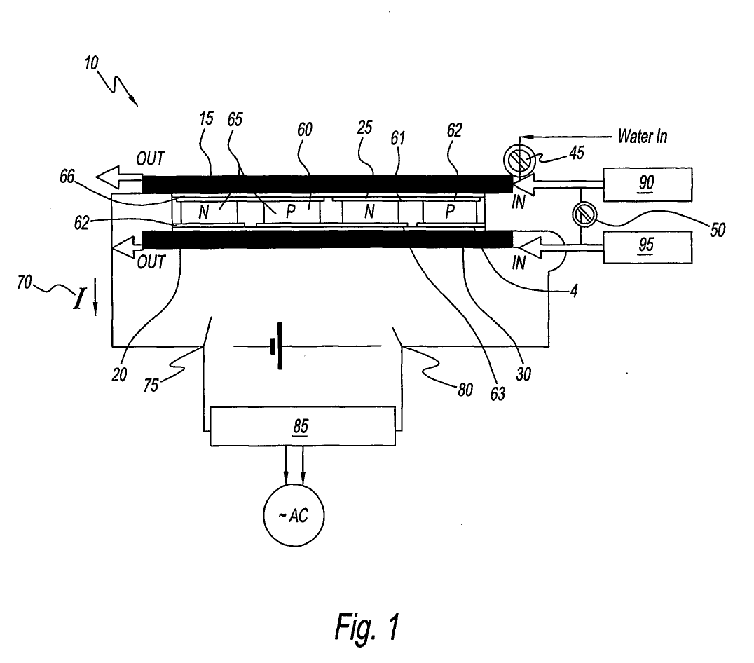

Referring to FIG. 1, the first embodiment of system 10 of the present invention is shown in the power generation mode. In this embodiment, system 10 has a heat exchanger 15 and a heat exchanger 20. Heat exchanger 15 has a high temperature from waste heat, which flows in the direction of arrow, relative to heat exchanger 20. Heat exchanger 20 is cooled by water. System 10 has closed valves 45 and 50 to permit heat exchangers 15 and 20 together to create a thermal gradient across thermoelectric devices 60. Thermoelectric devices 60 have opposing surfaces 61 and 63. This temperature gradient causes an electric current 70 to flow between terminals 75 and 80, a phenomenon known as the Seebeck effect.

Thermoelectric devices 60 located between heat exchangers 15 and 20 are arranged in an array of P and N junctions 65 that are configured in series by electrical contacts 62. When a thermal gradient is applied, a DC voltage develops across terminals 75 and 80 and current 70 flows across junctions 65. The DC voltage is converted to an AC voltage in the DC to AC inverter 85. Substrates 66 hold system 10 together and mechanically and electrically insulate thermoelectric junctions 65. Surface 61 of thermoelectric devices 60 becomes cool and surface 63 becomes hot. In this example, hot water 90 and cold water 95 flows through heat exchangers 15 and 20, respectively. Other modes of operation generating either a hot or cold flow of fluid could have been used as well.

Power created using thermoelectric junctions 65 of the embodiment on FIG. 1, can be used to supplement power to a CHP system that is short of electricity and abundant of waste heat in varied geographic locations and ambient environments. The systems need not be geographically isolated. Such systems could be onsite residential communities, office parks, campuses or stand alone buildings. The thermal gradient created by waste heat from a prime mover, for example, can be used to generate the thermal gradient necessary to generate the power to meet the peak electrical load. Alternatively, the power generated could be used during peak power demand times to power other components of a CHP system.

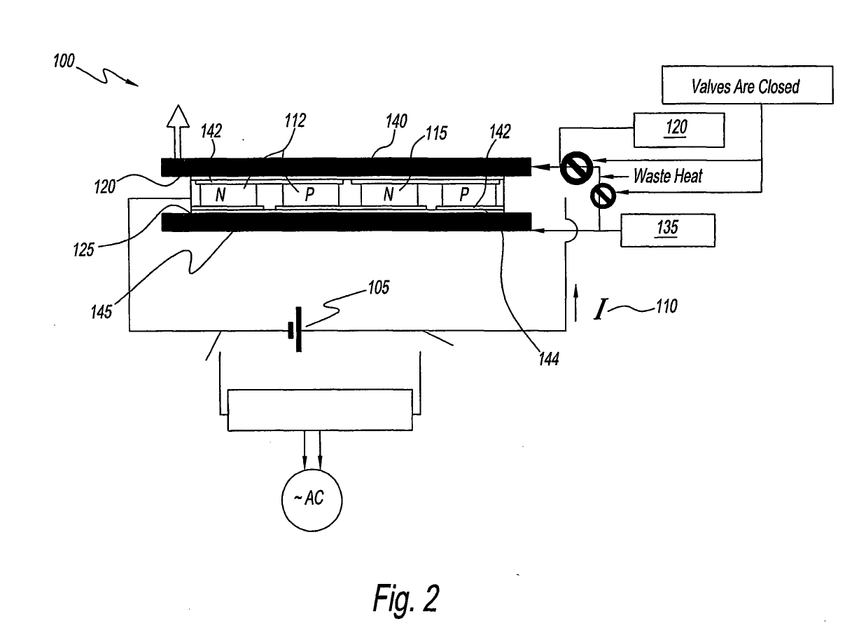

Referring to FIG. 2, a similar configuration of elements as those described in the first embodiment can be re-configured to provide a cooling system 100. In the second embodiment of the present invention, a DC voltage from a power source 105 is applied across system 100 and a current 110 flows in the direction shown. The P and N junctions 112 in the thermoelectric device 115 absorb heat from a surface 120, a working surface, and reject the heat to a surface 125 at the opposite side. Surface 120 where the heat is absorbed becomes cold and the opposite surface 125 where the heat is rejected becomes hot. This “heat pumping” phenomenon, known as the Peltier effect, is commonly used in thermoelectric refrigeration. In this embodiment water 130 that flows through a heat exchanger 140 provides heat to surface 120 to be cooled. Water 135 that flows through a heat exchanger 145 will transport heat away from surface 125 and be heated. System 100, like system 10, has electrical connectors 142 to connect pairs 112 in series. Substrates 144 hold system 100 together mechanically and electrically insulate pairs 112. Power source 105 used in this configuration can be a battery, a fuel cell, any other similar devices used to supply current, or simply from the excessive power generated by the CHP system.

The benefit of using the configuration of FIG. 2 is that during the period of which additional cooling is required, for example in the summer, and excessive electric power is generated by the CHP system, the system is able to provide additional cooling in addition to the conventional CHP system. Further, because the cooling system uses thermoelectric modules and does not use compressors or other traditional air conditioning components, minimal maintenance is required. Furthermore, the versatility of the system of FIG. 2, is such that by reversing the polarity of DC power supply 105 causes heat to be pumped in the opposite direction to convert cooling system 100 to a heating system.

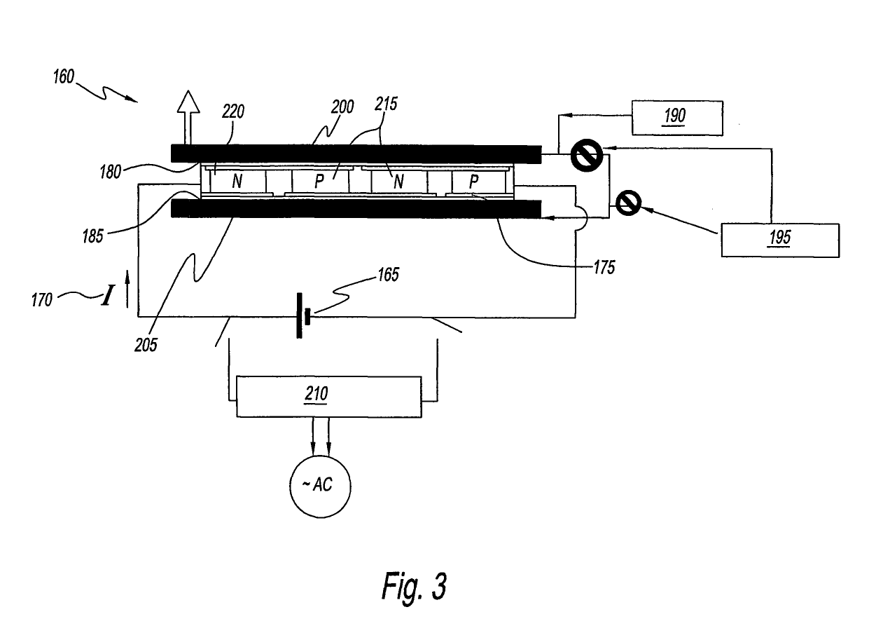

Referring to FIG. 3, in the third embodiment of the present invention, the thermoelectric system is configured as a heating system 160. In this embodiment, the same components as the embodiment of FIG. 2, are used except that the polarity of a power supply 165 is reversed and a current 170 flows in the opposite direction. In FIG. 3, current 170 flows through P and N pairs 215 of the thermoelectric devices 220 and a temperature gradient is generated at the surfaces 180 and 185. At surface 185 heat is absorbed and the surface becomes cool. Water 195 flowing through heat exchanger 205 is cooled. At surface 180, a working surface, heat is released in the direction of arrow and water flowing through heat exchanger 200 becomes hot.

The embodiment of the system 160 FIG. 3, can be used to provide additional heating in a CHP system during the cooler months of the year. The system of FIG. 3 also offers the same benefits of the configuration of FIG. 2. The primary benefit of the system is that a single system can independently meet the cooling, heating and power requirements of a system combined with a conventional CHP system throughout the year by generating DC current from waste heat, generating cooling or heating effect at a working surface.

While the instant disclosure has been described with reference to one or more exemplary embodiments, it will be understood by those skilled in the art that various changes may be made and equivalents may be substituted for elements thereof without departing from the scope thereof. In addition, many modifications may be made to adapt a particular situation or material to the teachings of the disclosure without departing from the scope thereof. Therefore, it is intended that the disclosure not be limited to the particular embodiment(s) disclosed as the best mode contemplated for carrying out this invention, but that the invention will include all embodiments falling within the scope of the appended claims.

1. A system for converting energy comprising:
an array of thermoelectric devices connected electrically in series between a first heat exchanger in contact with a first surface, said first surface being a working surface of said array and a second heat exchanger in contact with a second surface opposite said first surface of said array,
wherein said array of thermoelectric devices is capable of generating a DC current while a temperature gradient between said first surface and said second surface is applied and providing a thermal energy to a fluid at said working surface.

2. The system for converting energy of claim 1, wherein said first heat exchanger transports a first fluid and said second heat exchanger transports a second fluid to cause a thermal gradient to be generated in said array of thermoelectric devices.

3. The system for converting energy of claim 2, wherein said thermal gradient creates a DC electrical current in said array of thermoelectric devices that is inverted to AC current.

4. The system for converting energy of claim 1, wherein a DC current that is applied to said thermoelectric devices causes a change in temperature at said first surface of said array that is opposite in magnitude to a change in temperature at said second surface of said array.

5. The system for converting energy of claim 4, wherein said first surface of said array rejects heat and said second surface of said array absorbs heat.

6. The system for converting energy of claim 4, wherein said first surface of said array absorbs heat and said second surface of said array rejects heat.

7. The system for converting energy of claim 1, wherein said array of thermoelectric devices comprises pairs of alternating polarity semiconductor material that are each connected by an electrical contact.

8. A system for converting energy comprising:
an array of thermoelectric devices connected electrically in series; and
a first substrate covering one surface of said array and a different second covering an second surface of said array that is opposite said first surface of said array, said first substrate being a working surface;
wherein said array of thermoelectric devices is capable of generating a DC current while a temperature gradient between said first substrate and said second substrate is applied and providing thermal energy to said working surface.

9. The system of claim 8, wherein heat applied to one of said first and second substrates and the other of said first and second substrate is cooled applied the other of said first and second substrates causes a DC current to flow across said array of thermoelectric devices.

10. The system of claim 9, wherein a first heat exchanger that interfaces with said first substrate transports a hot fluid and said second heat exchanger that interfaces with said second substrate transmits a cold fluid.

11. The system of claim 9, wherein a DC current that is applied to said thermoelectric devices produces a temperature at said first surface of said array that is opposite in magnitude to a temperature at said second surface of said array.

12. The system of claim 11, wherein said first surface of said array releases heat and said second surface of said array absorbs heat.

13. The system of claim 11, wherein said first surface of said array absorbs heat and said second surface of said array releases heat.

14. The system of claim 9, wherein said array of thermoelectric devices comprise junctions of alternating polarity semiconductor material that are each connected by an electrical contact.

15. The system of claim 9, wherein said DC current that is created across said array of thermoelectric junctions is inverted to AC current in an AC converter.

16. The system of claim 9, wherein said thermal energy is either waste cooling or waste heating.

17. (canceled)

18. (canceled)
